(19) United States
(12) Patent Application Publication
(10) Pub. No.: US 2022/0052664 A1
(43) Pub. Date: Feb. 17, 2022

(54) LATERAL FEATURE CONTROL FOR REDUCING COUPLING VARIATION

(71) Applicant: RF360 EUROPE GMBH, Munchen (DE)

(72) Inventors: Maximilian SCHIEK, Munich (DE); Willi AIGNER, Munich (DE); Thomas MITTERMAIER, Dorfen (DE)

(21) Appl. No.: 16/995,491

(22) Filed: Aug. 17, 2020

(51) Int. Cl. H03H 3/02; G01R 29/22

(52) U.S. Cl. CPC H03H 3/02; H03H 2003/028; G01R 29/22

(57) ABSTRACT

In certain aspects, a method for reducing coupling coefficient variation includes receiving one or more measured coupling coefficients of one or more acoustic resonators, determining a coupling coefficient change based on the one or more measured coupling coefficients, and determining a change in a dimension of a lateral feature based on the determined coupling coefficient change.

### BACKGROUND

### Field

Aspects of the present disclosure relate generally to acoustic resonators, and more particularly, to reducing electromechanical coupling variation of acoustic resonators.

### Background

Acoustic resonators are used in a variety of applications including radio frequency (RF) filters in wireless devices. One type of acoustic resonator is the bulk acoustic wave (BAW) resonator which includes a piezoelectric layer sandwiched between two electrodes. BAW resonators are well suited for wireless devices because of their high performance, relatively low manufacturing cost, and compatibility with integrated circuit (IC) processes.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a method for reducing coupling coefficient variation. The method includes receiving one or more measured coupling coefficients of one or more acoustic resonators, determining a coupling coefficient change based on the one or more measured coupling coefficients, and determining a change in a dimension of a lateral feature based on the determined coupling coefficient change.

A second aspect relates to an apparatus for reducing coupling coefficient variation. The apparatus includes means for receiving one or more measured coupling coefficients of one or more acoustic resonators, means for determining a coupling coefficient change based on the one or more measured coupling coefficients, and means for determining a change in a dimension of a lateral feature based on the determined coupling coefficient change.

A third aspect relates to an apparatus. The apparatus includes a processor, a memory coupled with the processor, and instructions stored in the memory. The instructions are executable by the processor to cause the apparatus to receive one or more measured coupling coefficients of one or more acoustic resonators, determine a coupling coefficient change based on the one or more measured coupling coefficients, and determine a change in a dimension of a lateral feature based on the determined coupling coefficient change.

### BRIEF DESCRIPTION OF THE DRAWINGS

FIG. 1A shows a cross-sectional view of an exemplary bulk acoustic wave (BAW) resonator according to certain aspects of the present disclosure.

FIG. 1B shows a close-up view of exemplary lateral features of the BAW resonator according to certain aspects of the present disclosure.

FIG. 1C shows a top view of the exemplary BAW resonator according to certain aspects of the present disclosure.

FIG. 2 is a plot showing an example of passband variation due to coupling coefficient variation according to certain aspects of the present disclosure.

FIG. 3 is a plot showing an example of input voltage standing wave ratio (VSWR) variation due to coupling coefficient variation according to certain aspects of the present disclosure.

FIG. 4 is a plot showing an example of output VSWR variation due to coupling coefficient variation according to certain aspects of the present disclosure.

FIG. 5 is a plot showing changes in coupling coefficient with changes in the heights of lateral features of a BAW resonator according to certain aspects of the present disclosure.

FIG. 6 shows an example of a test structure for measuring the coupling coefficient of a BAW resonator according to certain aspects of the present disclosure.

FIG. 7 shows an example of a wafer map according to certain aspects of the present disclosure.

FIG. 8 shows an exemplary device in which aspects of the present disclosure may be implemented.

FIG. 9 is a flowchart illustrating an exemplary method for reducing coupling coefficient variation according to certain aspects of the present disclosure.

FIG. 10 shows an example of a bandpass filter including BAW resonators coupled in a ladder configuration according to certain aspects of the present disclosure.

FIG. 11 shows an example of a receive path of a wireless device according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

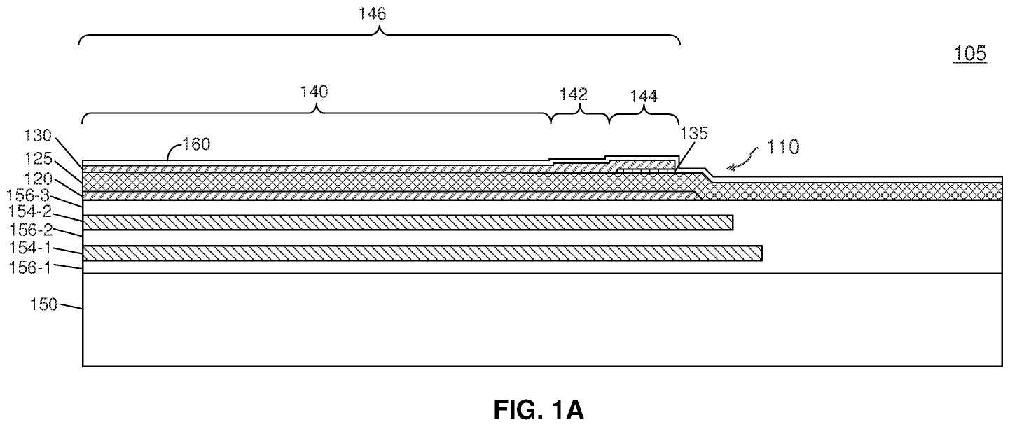

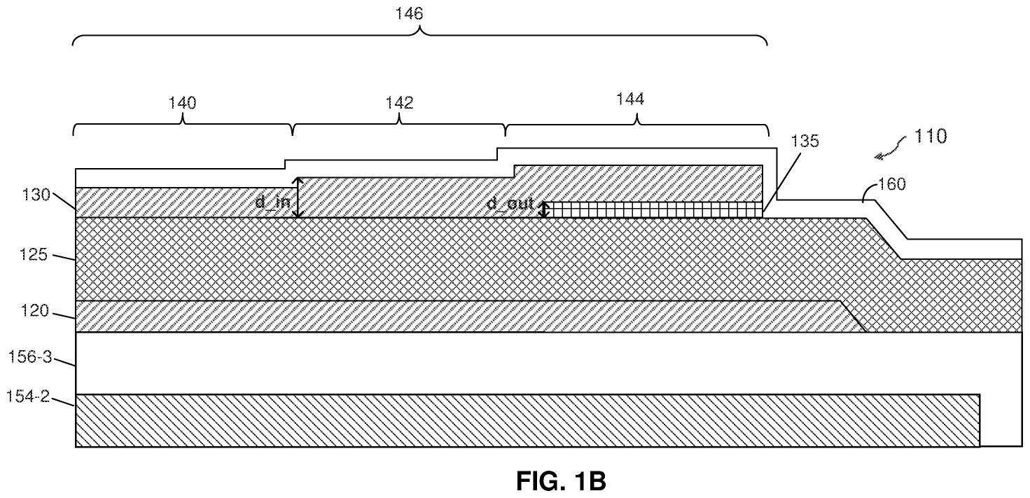

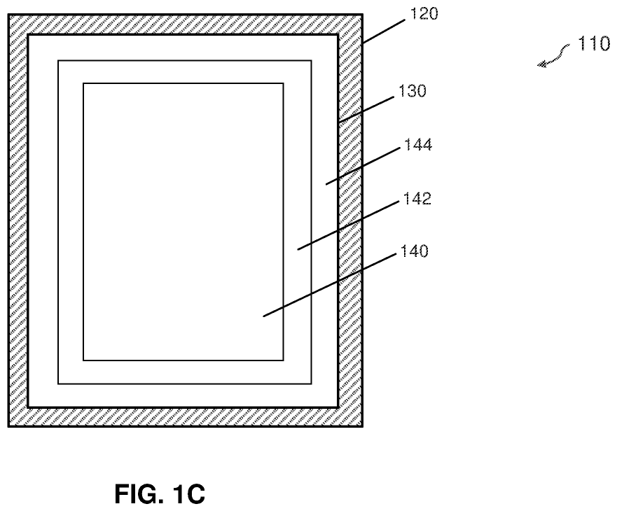

FIG. 1 shows an example of a bulk acoustic wave (BAW) resonator 110 integrated on a chip 105 according to certain aspects. The chip 105 may be part of a wafer before wafer dicing. The BAW resonator 110 includes a bottom electrode 120, a top electrode 130, and a piezoelectric layer 125 disposed between the top electrode 130 and the bottom electrode 120. The electrodes 120 and 130 may comprise tungsten, molybdenum, aluminum, aluminum copper, ruthenium, and/or another material. The piezoelectric layer 125 may comprise aluminum nitride (AlN), zinc oxide (ZnO), or another piezoelectric material. The chip 105 also includes a passivation layer 160 (e.g., silicon nitride) over the BAW resonator 110 to protect the BAW resonator 110 from the external environment. Note that FIG. 1A shows the right half of the BAW resonator 110. The BAW resonator 110 may be symmetrical in which the left half (not shown) of the BAW resonator 110 is similar to the right half of the BAW resonator 110. Although FIG. 1 shows one BAW resonator 110, it is to be appreciated that multiple BAW resonators 110 may be integrated on the chip 105.

The BAW resonator 110 is configured to convert electrical energy from an electrical signal applied to the BAW resonator 110 into acoustic energy in the piezoelectric layer 125 with a resonance frequency that depends on the thicknesses of the piezoelectrical layer 125 and the electrodes 120 and 130.

The chip 105 may include a Bragg mirror (also referred to as a Bragg reflector) beneath the bottom electrode 120 to acoustically isolate the substrate 150 (e.g., silicon substrate) from the BAW resonator 110. The Bragg mirror includes a stack of layers that alternate between high acoustic impedance layers 154-1 and 154-2 (e.g., tungsten) and low acoustic impedance layers 156-1 to 156-3 (e.g., silicon oxide). The Bragg mirror is configured to reflect acoustic waves from the BAW resonator 110 to prevent the acoustic waves from propagating downward to the substrate 150. Air above the BAW resonator 110 provides a high acoustic reflective interface that prevents acoustic waves from propagating upward. Thus, the Bragg mirror and the air interface help confine acoustic energy to the BAW resonator 110. In this example, the BAW resonator 110 may be referred to as a solidly mounted BAW (SMR-BAW) resonator. Alternatively, the chip 105 may have an air cavity beneath the bottom electrode 120 instead of the Bragg mirror to reflect acoustic waves.

The BAW resonator 110 also includes a first lateral feature 142 and a second lateral feature 144 to prevent lateral acoustic energy leakage from the active region 146 of the BAW resonator 110. The active region 146 corresponds to the overlapping area of the top electrode 130, the piezoelectric layer 125, and the bottom electrode 120. The first and second lateral features 142 and 144 are formed along the perimeter of the active region 146. This can be seen in FIG. 1C, which shows a top view of the BAW resonator 110. As shown in FIG. 1C, the first and second lateral features 142 and 144 surround an inner region 140 of the active region 146. The inner region 140 makes up most of the active region 146 in which the thickness of the top electrode 130 in the inner region 140 may be set based on a desired resonance frequency for the BAW resonator 110. For ease of illustration, the piezoelectric layer 125 and the passivation layer 160 are not shown in FIG. 1C. Although the BAW resonator 110 is shown having a rectangular shape in the example in FIG. 1C, it is to be appreciated that the BAW resonator 110 may have another shape.

Referring to FIG. 1B, which shows a close-up view of the lateral features 142 and 144, the first lateral feature 142 includes a portion of the top electrode 130 surrounding the inner region 140. The portion of the top electrode 130 in the first lateral feature 142 has a different thickness (i.e., height) than the portion of the top electrode 130 in the inner region 140. The thickness (i.e., height) difference induces an acoustic velocity shift and hence cut-off frequency shift between the inner region 140 and the first lateral feature 142 that prevents acoustic energy from leaking out of the BAW resonator 110 in the lateral direction. In FIG. 1B, the thickness (i.e., height) of the top electrode 130 in the first lateral feature 142 is labeled d_in. In the example in FIG. 1B, the thickness d_in of the top electrode 130 in the first lateral feature 142 is greater than the thickness of the top electrode 130 in the inner region 140. Thus, in this example, the first lateral feature 142 comprises a thickened portion of the top electrode 130.

The second lateral feature 144 includes a portion of the top electrode 130 surrounding the first lateral feature 142 along the outer edge of the active region 146. The portion of the top electrode 130 in the second lateral feature 144 has a different thickness (i.e., height) than the portion of the top electrode 130 in the inner region 140. The thickness of the top electrode 130 in the second lateral feature 144 may be approximately equal to the thickness of the top electrode 130 in the first lateral feature 142. However, it is to be appreciated that this need not be the case. The second lateral feature 144 also includes a dielectric layer 135 (e.g., silicon oxide) between the top electrode 130 and the piezoelectric layer 125. In FIG. 1B, the thickness (i.e., height) of the dielectric layer 135 is labeled d_out.

An important parameter of the BAW resonator 110 is the effective electromechanical coupling coefficient k²eff (hereinafter “coupling coefficient” for short) of the BAW resonator 110, which measures conversion efficiency between electrical energy and acoustic energy. The coupling coefficients of BAW resonators define achievable filter characteristics including bandwidth and voltage standing wave ratio (VSWR). A challenge with mass production of BAW resonators is that the coupling coefficients of BAW resonators vary due to layer thickness variation, material property (e.g., piezo stress e33) variation, and/or film stress variation.

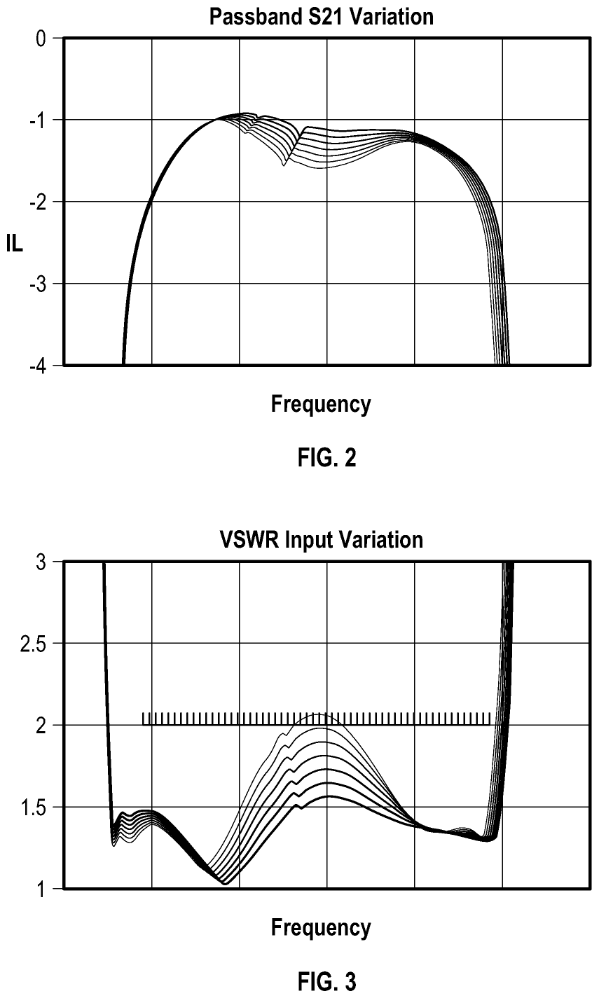

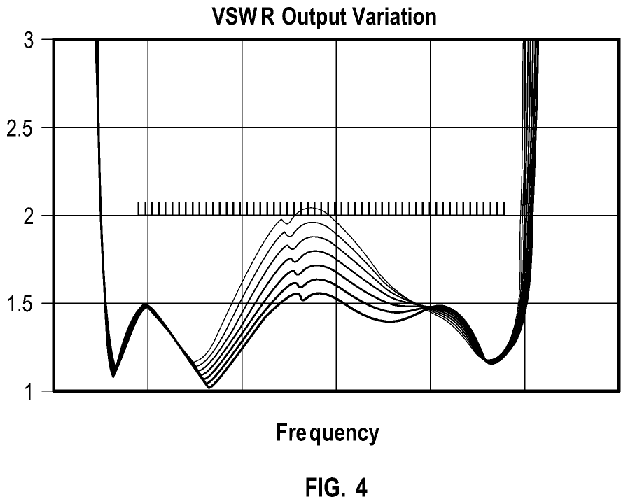

The coupling coefficient variation of the BAW resonators leads to passband and VSWR variation of filters incorporating the BAW resonators. In this regard, FIG. 2 shows passband variation of the filters due to coupling coefficient variation. In FIG. 2, each curve shows the passband for a different coupling coefficient where the vertical axis corresponds to insertion loss (IL) and the horizontal axis corresponds to frequency. FIG. 3 shows input VSWR variation of the filters due to coupling coefficient variation, where each curve shows the input VSWR over frequency for a different coupling coefficient. FIG. 4 shows output VSWR variation of the filters due to the coupling coefficient variation, where each curve shows the output VSWR over frequency for a different coupling coefficient. As shown in FIGS. 2 to 4, coupling coefficient variation of BAW resonators can lead to large variations in the passband, input VSWR, and output VSWR of filters incorporating the BAW resonators.

The specification for filters may require that the passband, input VSWR, and output VSWR of each filter be within narrow ranges defined in the specification. A challenge with meeting the specification is that large variations in the passband, input VSWR, and output VSWR due to coupling coefficient variation can cause many filters to fail to meet the specification, resulting in lower yields.

To address the above challenge, aspects of the present disclosure reduce coupling coefficient variation by taking advantage of a dependency of the coupling coefficients of BAW resonators on the dimensions of one or more lateral features of the BAW resonators. In these aspects, one or more dimensions (height and/or width) of the one or more lateral features are adjusted based on coupling coefficient measurements to reduce coupling coefficient variation, as discussed further below.

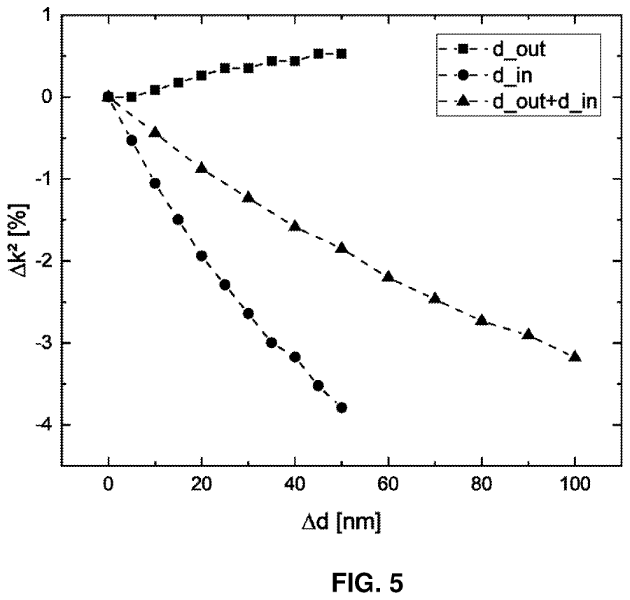

FIG. 5 is a plot showing changes in the coupling coefficient of a BAW resonator with changes in the height d_in of the top electrode 130 in the first lateral feature 142, changes in the height d_out of the dielectric layer 135, and changes in the combined height (labeled “d_out+d_in”). In this example, the height of the top electrode 130 in the second lateral feature 144 is approximately the same as the height of the top electrode 130 in the first lateral feature 142. However, it is to be appreciated that this need not be the case.

As shown in FIG. 5, the coupling coefficient depends on the height d_in of the top electrode 130 in the first lateral feature 142 and the height d_out of the dielectric layer 135. Because of this dependency, the coupling coefficient can be adjusted by adjusting the height d_in of the top electrode 130 in the first lateral feature 142 and/or the height d_out of the dielectric layer 135. The change in the height d_out and/or the height d_in needed to achieve a desired change in the coupling coefficient can be readily determined from the plot in FIG. 5.

In general, the relationship between changes in the coupling coefficient and changes in the height d_in and/or the height d_out may be determined through computer simulations and/or measurements. Based on the determined relationship, the change in the height d_in and/or the height d_out needed to achieve a desired change in the coupling coefficient can be readily determined.

In certain aspects, the relationship between changes in the coupling coefficient and changes in a height of a lateral feature may be approximated by a function (e.g., a linear function, a piecewise function, or another type of function). In these aspects, the function may be fitted to measurement points of changes in the coupling coefficient with changes in the height of the lateral feature using least squares fit or another fitting technique. The measurement points may be obtained by measuring BAW resonators with different lateral feature heights and/or computer simulations. For the example of a linear function (i.e., line), a steeper slope is indicative of a higher sensitivity of the coupling coefficient to changes in the height of the lateral feature. In the example in FIG. 5, the measurement points for height d_in are represented by dots, the measurement points for height d_out are represented by squares, and the measurements point for the combined height d_out+d_in are represented by triangles.

The coupling coefficient is also dependent on the width of the first lateral feature 142 and the width of the second lateral feature 144. Thus, adjustments to the coupling coefficient can also be achieved by adjusting the width of the first lateral feature 142 and/or the width of the second lateral feature 144. The relationship between changes in the coupling coefficient and changes in the width of the first lateral feature 142 and/or the width of the second lateral feature 144 may be determined through computer simulations and/or measurements. Based on the determined relationship, the change in the width of the first lateral feature 142 and/or the width of the second lateral feature 144 needed to achieve a desired change in the coupling coefficient can be readily determined.

The amount of change in the coupling coefficient that can be achieved by adjusting one or more dimensions (e.g., height and/or width) of one or more lateral features may be larger than the variation in the coupling coefficient caused by process variation during production. Thus, the coupling coefficient variation can be significantly reduced by adjusting one or more dimensions (e.g., height and/or width) of the one or more lateral features, resulting in a tighter distribution of VSWR in filters incorporating the BAW resonators.

In certain aspects, the coupling coefficients of BAW resonators are measured. This information is used to determine the amount by which the coupling coefficients of the BAW resonators need to be shifted (i.e., changed) so that the coupling coefficients fall within a coupling coefficient range meeting a specification.

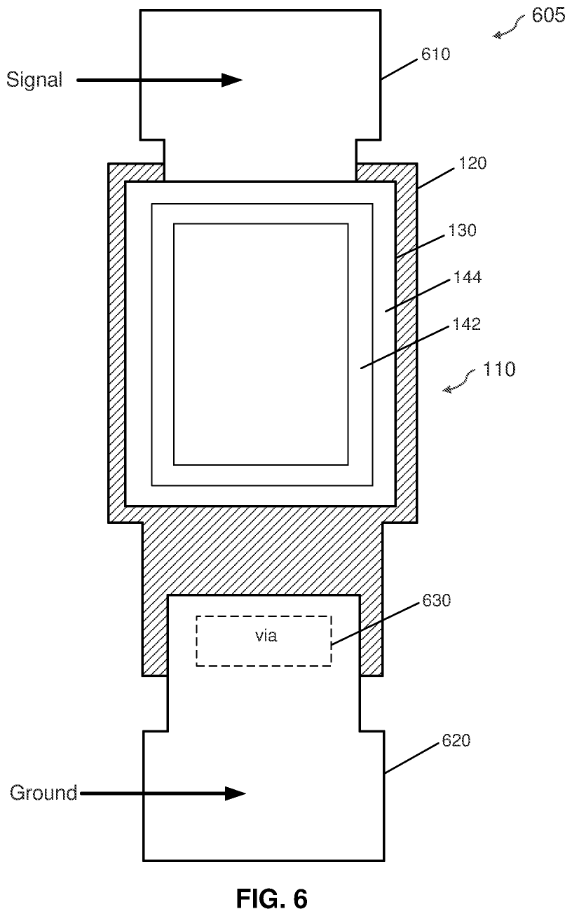

In this regard, FIG. 6 shows an exemplary test structure 605 for measuring the coupling coefficient of a BAW resonator. The test structure 605 includes the BAW resonator 110, a first pad 610, a second pad 620, and a via 630. The first pad 610 is electrically coupled to the top electrode 130 of the BAW resonator 110 and is configured to provide external measurement equipment (e.g., vector network analyzer (VNA)) with access to the top electrode 130. The second pad 620 is electrically coupled to the bottom electrode 120 of the BAW resonator 110 through the via 630 and is configured to provide the external measurement equipment with access to the bottom electrode 120. The vias 630 is coupled between the second pad 620 and a portion of the bottom electrode 120 outside of the active region 146. The via 630 passes through an opening in the piezoelectric layer 125 to electrically couple the second pad 620 with the bottom electrode 120. Note that the piezoelectric layer 125 is not shown in FIG. 6 for ease of illustration.

To measure the coupling coefficient of the BAW resonator 110, a probe of the measurement equipment is placed in electrical contact with the first pad 610 and the second pad 620 is grounded. The measurement equipment then applies one or more test signals to the top electrode 130 to measure one or more parameters of the BAW resonator 110 (e.g., S₁₁ parameter, Y₁₁ parameter, etc.). For example, the measurement equipment may measure admittance of the BAW resonator 110 over frequency. From the admittance, the resonance frequency and the antiresonance frequency of the BAW resonator 110 may be determined in which the resonance frequency is the frequency at which the admittance is high (e.g., maximum) and the antiresonance is the frequency at which the admittance is low (e.g., minimum). The coupling coefficient of the BAW resonator 110 may then be determined, for example, based on the following:

$${k}_{e f f}^{2} = \frac{{π}^{2}}{4} ( \frac{{f}_{s}}{{f}_{p}} ) \cdot ( \frac{{f}_{p} - {f}_{s}}{{f}_{p}} ) \qquad ( 1 )$$

where fₛ is the resonance frequency (also referred to as series resonance) and fₚ is the antiresonance frequency (also referred to as parallel resonance). It is to be appreciated that the present disclosure is not limited to equation (1) to define the coupling coefficient. The present disclosure covers other equations that may be used in the art to define the coupling coefficient. It is also to be appreciated that the coupling coefficient may be determined using other measurement parameters.

Thus, the coupling coefficient of the BAW resonator 110 may be measured using the exemplary test structure shown in FIG. 6. However, it is to be appreciated that the present disclosure is not limited to the exemplary test structure shown in FIG. 6 and that another test structure may be used to measure the coupling coefficient of the BAW resonator 110.

In certain aspects, a wafer includes multiple test structures distributed on the wafer for measuring the coupling coefficients of multiple BAW resonators (e.g., multiple instances of BAW resonator 110) distributed on the wafer. In these aspects, the coupling coefficient of each of these BAW resonators may be measured (e.g., using the exemplary measurement procedure discussed above). In certain aspects, the measured BAW resonators on the wafer may be assumed to be representative of unmeasured BAW resonators on the wafer (e.g., BAW resonators without test structures).

The measured coupling coefficients for the wafer may be used to determine a coupling coefficient shift (i.e., change) using any one of several exemplary techniques according to aspects of the present disclosure. In one example, a mean of the measured coupling coefficients is determined. In this example, the coupling coefficient shift is determined by determining a difference between the mean of the measured coupling coefficients and a target coupling coefficient (e.g., a coupling coefficient meeting a specification), and using the difference for the coupling coefficient shift (i.e., change). In another example, a range of the measured coupling coefficients is determined. In this example, the coupling coefficient shift may be determined by determining a difference between a center of the range of the measured coupling coefficients and the target coupling coefficient, and using the difference for the coupling coefficient shift (i.e., change).

After the coupling coefficient shift is determined, a change in one or more lateral feature dimensions needed to achieve the coupling coefficient shift (i.e., change) is determined. For example, if the lateral feature dimension is the height d_in of the top electrode 130 in the first lateral feature 142, then the change in the height d_in needed to achieve the coupling coefficient shift may be determined (e.g., from the exemplary plot in FIG. 5). As discussed above, the relationship between changes in the coupling coefficient and changes in one or more lateral feature dimensions may be determined through computer simulations and/or measurements. Based on the determined relationship, the change in the one or more lateral feature dimensions needed to achieve the coupling coefficient shift (i.e., change) may be determined. As discussed above, a function (e.g., linear function) relating changes in the coupling coefficient to changes in one or more lateral feature dimensions may be determined (e.g., by fitting the function to measurement points). In this example, the change in the one or more lateral feature dimensions needed to achieve the coupling coefficient shift (i.e., change) may be determined using the function.

After the change in the one or more lateral feature dimensions is determined, the one or more lateral feature dimensions may be adjusted to realize the change. The change may be applied globally to the wafer (e.g., applied to each BAW resonator on the wafer). For example, if the change is a reduction in the height d_in by Δd, then the portion of the top electrode 130 in the first lateral feature 142 of each BAW resonator may be trimmed by Δd (e.g., using ion beam etching) to realize the change. For the example in which the height of the top electrode 130 in the second lateral feature 144 is also d_in, the height of the top electrode 130 in the second lateral feature 144 may also be trimmed by Δd. In general, a reduction in the height of a lateral feature may be realized by trimming the lateral feature using ion beam etching and/or another etching technique. Other exemplary techniques for changing one or more lateral feature dimensions are discussed further below. In this example, changing of one or more lateral features dimensions for each wafer one of multiple wafers based on a respective coupling coefficient shift reduces the coupling coefficient variation between the wafers and hence reduces the coupling coefficient variation across the wafers.

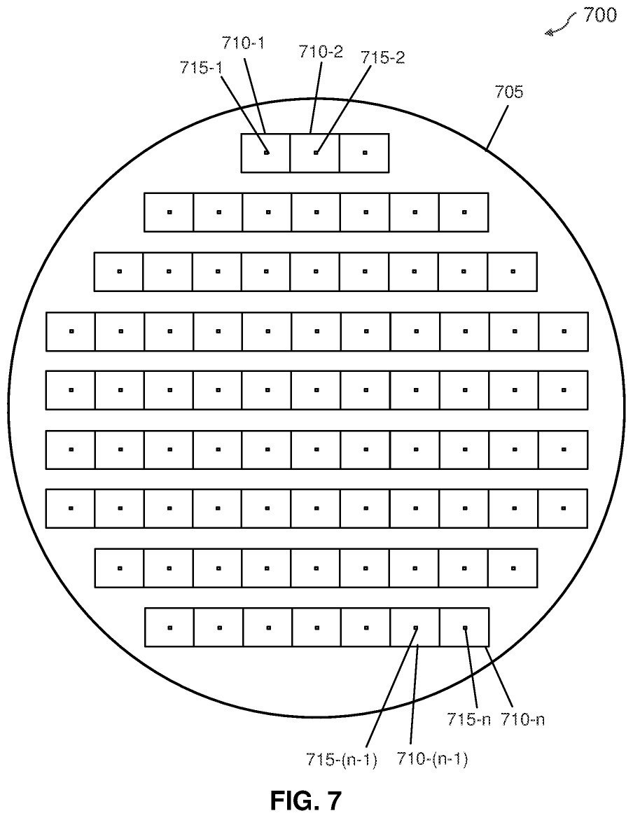

In certain aspects, the wafer is partitioned into two or more regions (e.g., blocks). In this regard, FIG. 7 shows an example of a wafer map 700 for a wafer 705 partitioned into multiple regions 710-1 to 710-n. In this example, the wafer 705 includes a test structure 715-1 to 715-n in each region 710-1 to 710-n. Each test structure 715-1 to 715-n may be implemented with the exemplary test structure 605 shown in FIG. 6 or another test structure. As discussed above, a test structure includes a BAW resonator and structures (e.g., pads) to facilitate testing of the BAW resonator. In the example in FIG. 7, each test structure 715-1 to 715-n is centrally located in the respective region 710-1 to 710-n. However, it is to be appreciated that this need not be the case. Note that, in FIG. 7, only some of the regions 710-1 to 710-n and some of the test structures 715-1 to 715-n are identified by reference numbers for ease of illustration.

Each region 710-1 to 710-n of the wafer 705 may include multiple BAW resonators (not shown) in which the BAW resonator in the test structure in the region may be assumed to be representative of the multiple BAW resonators in the region. In certain aspects, a coupling coefficient shift (i.e., change) may be determined for each region 710-1 to 710-n as follows. For each region 710-1 to 710-n, the coupling coefficient of the BAW resonator in the respective test structure 715-1 to 715-n is measured. A coupling coefficient shift (i.e., change) is then determined for each region 710-1 to 710-n based on the measured coupling coefficient for the BAW resonator in the respective test structure 715-1 to 715-n. In one example, the coupling coefficient shift for each region may be determined by determining a difference between the respective measured coupling coefficient and a target coupling coefficient (e.g., a coupling coefficient meeting a specification), and using the difference for the coupling coefficient shift (i.e., change).

After the coupling coefficient shift for each region 710-1 to 710-n of the wafer 705 is determined, a change in one or more lateral feature dimensions needed to achieve the coupling coefficient shift (i.e., change) for each region 710-1 to 710-n is determined (e.g., using any of the techniques discussed above). After the change in the one or more lateral feature dimensions is determined for each region 710-1 to 710-n of the wafer 705, the one or more lateral feature dimensions in each region 710-1 to 710-n is adjusted to realize the corresponding change (e.g., using ion beam etching or another etching process). In each region 710-1 to 710-n, the determined change in the one or more lateral feature dimensions for the region may be applied to all the BAW resonators (not shown) in the region 710-1 to 710-n. In this example, the changing of the one or more lateral features dimensions in each region 710-1 to 710-n based on the respective coupling coefficient shift reduces the coupling coefficient variation between the regions 710-1 to 710-n and hence reduces the coupling coefficient variation across the wafer 705.

It is to be appreciated that each region 710-1 to 710-n is not limited to one test structure 715-1 to 715-n. For example, in some implementations, each region 710-1 to 710-n may include multiple test structures. In this example, a coupling coefficient shift (i.e., change) may be determined for each region 710-1 to 710-n as follows. For each region 710-1 to 710-n, the coupling coefficients of the BAW resonators in the respective test structures are measured. A coupling coefficient shift (i.e., change) is then determined for each region 710-1 to 710-n based on the measured coupling coefficients for the BAW resonators in the respective test structures. In one example, the coupling coefficient shift for each region may be determined by computing a mean of the measured coupling coefficients for the BAW resonators in the respective test structures, determining a difference between the mean of the measured coupling coefficients and a target coupling coefficient (e.g., a coupling coefficient meeting a specification), and using the difference for the coupling coefficient shift (i.e., change).

In certain aspects, the coupling coefficient shift for a BAW resonator on a wafer may be determined using the test structure on the wafer located nearest to the BAW resonator. In this example, the wafer includes multiple test structures (e.g., test structures 715-1 to 715-n) distributed on the wafer. In this example, a coupling coefficient shift is determined for each test structure by measuring the coupling coefficient of the BAW resonator in the test structure and determining the coupling coefficient shift for the test structure based on the measured coupling coefficient (e.g., by determining the difference between the measured coupling coefficient and a target coupling coefficient). After the coupling coefficient shift is determined for each test structure on the wafer, the coupling coefficient shift for each one of multiple BAW resonators on the wafer may be determined as follows. For each of the BAW resonators, the respective coupling coefficient shift is determined by determining the test structure located nearest to the BAW resonator on the wafer and using the coupling coefficient shift determined for the nearest test structure for the BAW resonator. In one example, a wafer may be partitioned into multiple regions (e.g., regions 710-1 to 710-n) in which the resonators (not shown) in each region are located nearest to a test structure (e.g., test structure 715-1 to 715-n) located in the region. In this example, the test structure in each region may be centrally located in the region.

In certain aspects, interpolation may be employed to determine a coupling coefficient shift for a region on a wafer using coupling coefficient measurements for one or more other regions on the wafer. In these aspects, a coupling coefficient for the region may be interpolated from coupling coefficient measurements for one or more other regions on the wafer. The interpolation may include linear interpolation, piecewise interpolation, etc. Once the coupling coefficient of the region is determined using interpolation, the coupling coefficient shift for the region may be determined (e.g., by determining the difference between the interpolated coupling coefficient and a target coupling coefficient). For example, if the region on the wafer is located between two other regions on the wafer, then the coupling coefficient for the region may be interpolated by determining an average of the coupling coefficient measurements for the two other regions on the wafer. Interpolation may be used to reduce the number of coupling coefficient measurements needed to determine coupling coefficient shifts for the regions on the wafer by only performing coupling coefficient measurements for a subset of the regions and using interpolation for the remaining regions on the wafer.

In certain aspects, the coupling coefficient variation on a wafer may have a profile that is approximately wedge shaped or radial symmetric. For a radial symmetric profile, BAW resonators that are located the same distance from the center of the wafer have approximately the same coupling coefficient. The wedge-shaped profile or radial symmetric profile of the coupling coefficient variation on the wafer may be a characteristic of a deposition process (e.g., chemical vapor deposition, sputter deposition, or evaporation deposition) used to form the lateral features of BAW resonators on the wafer. In these aspects, the profile of the coupling coefficient variation on the wafer may be used to interpolate a coupling coefficient for a region on the wafer based on coupling coefficient measurements for one or more other regions on the wafer. For instance, for the example of interpolation based on a radial symmetric profile (i.e., radial symmetric interpolation), the coupling coefficient for a region may be determined to be approximately equal to a measured coupling coefficient for another region that is located approximately the same distance from the center of the wafer as the region.

As discussed above, the height d_in of the top electrode 130 in the first lateral feature 142 may be trimmed to realize a desired coupling coefficient shift (i.e., change) using ion beam etching. In this example, an ion beam machine may trim the height d_in by moving the wafer under the ion beam and precisely controlling the velocity of the movement based on the desired trim. In this example, the lower the velocity, the greater the amount of exposure to the ion beam and the greater the amount of trimming. In this example, the amount by which the height d_in is to be reduced (i.e., trimmed) may be input to the ion beam machine, and a program on the ion beam machine may translate the height reduction into the corresponding wafer velocity. For the example in which the height of the top electrode 130 in the second lateral feature 144 is also d_in, the ion beam machine may also trim the top electrode 130 in the second lateral feature 144 by the same amount. In general, the height of a lateral feature may be trimmed by a precise amount using ion beam etching and/or another etching technique.

For the example where the wafer is partitioned into regions (e.g., 710-1 to 710-n), the height change d_in (e.g., trim) for each region may be determined from the coupling coefficient shift for the region. The ion beam machine may then control the ion beam exposure for each region based on the respective height change to achieve the desired trim for each region.

Wafers are typically processed in lots (i.e., batches) in which wafers in the same lot may be processed as a group using the same processing equipment under similar environmental conditions. In some cases, process variation between wafers in the same lot (i.e., batch) may be relatively small compared with lot-to-lot process variation. In these cases, a coupling coefficient shift determined based on measurements for one wafer in a lot may be applied to other wafers in the same lot, as discussed further below.

In one example, the coupling coefficients of BAW resonators on a wafer in a lot may be measured (e.g., using the exemplary measurement procedure discussed above). A coupling coefficient shift (i.e., change) may then be determined based on the measurements using any one of the exemplary techniques discussed above. After the coupling coefficient shift is determined, a change in one or more lateral feature dimensions needed to achieve the coupling coefficient shift (i.e., change) is determined (e.g., using any of the techniques discussed above).

After the change in the one or more lateral feature dimensions is determined, the one or more lateral feature dimensions are adjusted for each of the other wafers in the lot to realize the change. The one or more lateral feature dimensions may be adjusted for the other wafers, for example, by adjusting one or more process steps for the other wafers to realize the change. For instance, in one example, the width of a lateral feature may be defined by a mask during a photolithographic process. In this example, a change in the width of the lateral feature may be realized by changing the mask. In another example, a material for a lateral feature may be formed on a wafer and a portion of the material may be etched away using an etching process to form the lateral feature. In this example, a change in the height of the lateral feature may be realized by adjusting the depth of the etching process.

For the example where a wafer is partitioned into regions (e.g., 710-1 to 710-n), the change in the one or more lateral feature dimensions may be determined for each region of the wafer (e.g., using any of the techniques discussed above). A wafer map may then be generated, in which the wafer map indicates the change in the one or more lateral feature dimensions for each region of a wafer. The one or more lateral feature dimensions may then be adjusted for each of the other wafers in the lot based on the wafer map.

Although aspects of the present disclosure are discussed above using the examples of BAW resonators, it is to be appreciated that aspects of the present disclosure may also be applied to other types of acoustic resonators to reduce coupling coefficient variation. For example, aspects of the present disclosure may be applied to surface acoustic wave (SAW) resonators to reduce coupling coefficient variation across SAW resonators. In this example, a SAW resonator may include two interdigitated electrodes disposed on the top surface of a piezoelectric layer in which the electrodes are separated from each other in the lateral direction. In this example, each electrode may include one or more lateral features to help confine acoustic waves to the active region of the SAW resonator. Like the BAW resonators discussed above, aspects of the present disclosure may be used to reduce coupling coefficient variation by adjusting (e.g., trimming) the lateral features of the SAW resonators based on coupling coefficient measurements of the SAW resonators.

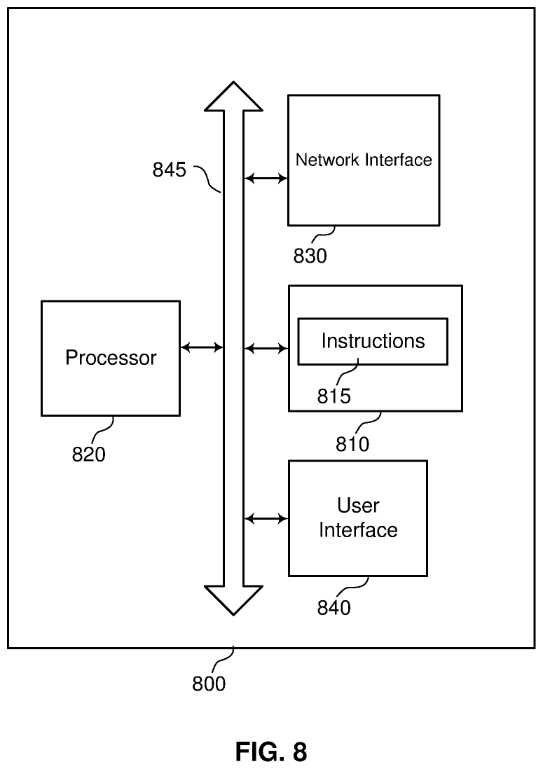

FIG. 8 illustrates an example device 800 according to certain aspects of the present disclosure. The device 800 may be configured to perform one or more of the operations described herein. The device 800 may include a processor 820, a memory 810, a network interface 830, and a user interface 840. These components may be in electronic communication via one or more buses 845.

The memory 810 may store instructions 815 that are executable by the processor 820 to cause the device 800 to perform one or more of the operations described herein. The operations may include one or more of the following: measuring coupling coefficients of acoustic resonators, determining a coupling coefficient shift (i.e., change) based on coupling coefficient measurements, and determining a change in one or more lateral feature dimensions to achieve a coupling coefficient shift. The processor 820 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof. The memory 810 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof.

The network interface 830 is configured to interface the device 800 with one or more other devices. For example, the network interface 830 may receive raw measurement data for a BAW resonator (e.g., from a probe tester) and the processor 820 may process the received measurement data to determine the coupling coefficient of the BAW resonator. In another example, after the processor 820 determines a change in one or more lateral feature dimensions, the network interface 830 may send the change to processing equipment to implement the change. For the example where the change involves trimming the height of a lateral feature, the network interface 830 may send the change to an ion beam machine that performs the trimming.

The user interface 840 may be configured to receive data from a user (e.g., via keypad, mouse, etc.) and provide the data to the processor 820. The user interface 840 may also be configured to output data from the processor 820 to the user (e.g., via a display, a speaker, etc.). In this case, the data may undergo additional processing before being output to the user.

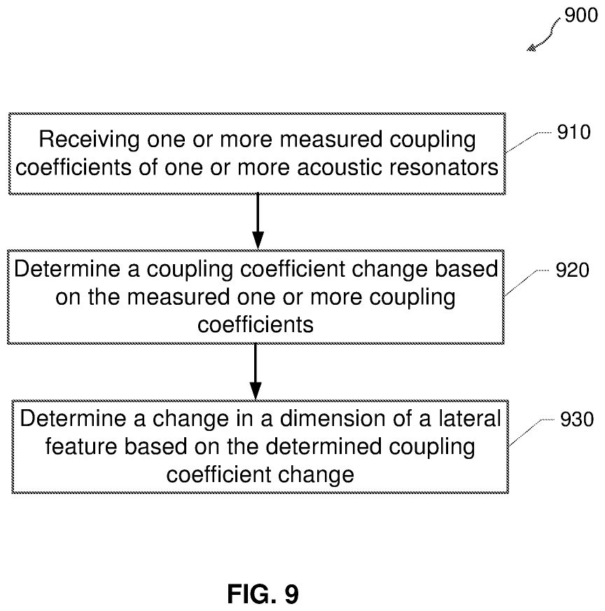

FIG. 9 shows an exemplary method 900 for reducing coupling coefficient variation according to certain aspects of the present disclosure.

At block 910, one or more measured coupling coefficients of one or more acoustic resonators are received. For example, the one or more acoustic resonators may include one or more BAW resonators (e.g. one or more instances of BAW resonator 110) or one or more SAW resonators. The one or more measured coupling coefficients may be received using the network interface 830. The one or more measured coupling coefficients of the one or more acoustic resonators may be obtained by measurements performed on the one or more acoustic resonators. The measurements may be performed using test structures (e.g., test structures 715-1 to 715-n), as discussed above.

At block 920, a coupling coefficient change is determined based on the one or more measured coupling coefficients. For example, the coupling coefficient change may be determined by the processor 820.

At block 930, a change in a dimension of a lateral feature is determined based on the determined coupling coefficient change. For example, the change in the dimension of the lateral feature may be determined by the processor 820 (e.g., based on a predetermined relationship between changes in the coupling coefficient and changes in the dimension of the lateral feature). In one example, the dimension comprises a height (e.g., height d_in) of the lateral feature. In another example, the dimension comprises a width of the lateral feature.

In certain aspects, determining the coupling coefficient change may include determining a mean of the one or more measured coupling coefficients, and determining a difference between the mean of the one or more measured coupling coefficients and a target coupling coefficient.

In certain aspects, the one or more acoustic resonators include one acoustic resonator, and determining the coupling coefficient change may include determining a difference between the measured coupling coefficient of the one acoustic resonator and a target coupling coefficient.

In certain aspects, determining the coupling coefficient change may include interpolating a coupling coefficient based on the one or more measured coupling coefficients, and determining a difference between the interpolated coupling coefficient and a target coupling coefficient. The interpolation may include one of linear interpolation, piecewise interpolation, radial symmetric interpolation, or another type of interpolation.

For an example of a wafer (e.g., wafer 705) partitioned into region (e.g., regions 710-1 to 710-n), the exemplary method 900 may be performed for each region of the wafer to determine a coupling coefficient change for each region.

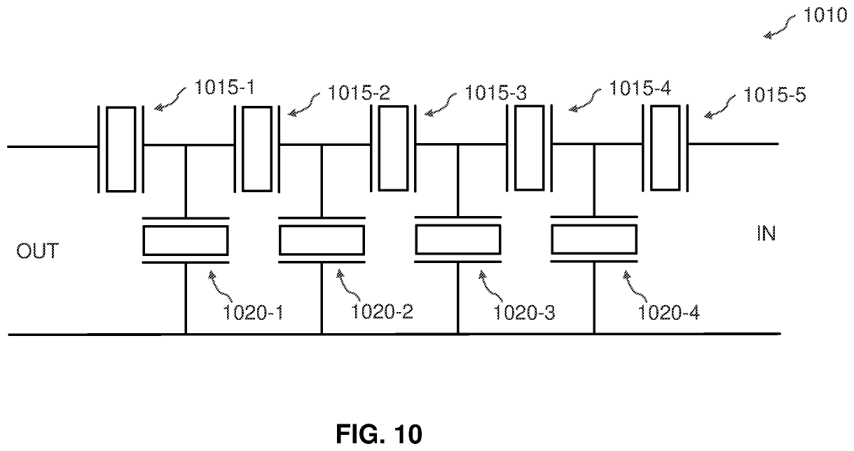

BAW resonators may be used in a variety of applications. For example, BAW resonators may be used to form bandpass filters, notch filters, multiplexers, duplexers, extractors, etc. In this regard, FIG. 10 shows an example of a bandpass filter 1010 including series BAW resonators 1015-1 to 1015-5 and shunt BAW resonators 1020-1 to 1020-4 coupled in a ladder configuration. Each of the BAW resonators 1015-1 to 1015-5 and 1020-1 to 1020-4 may be implemented with the exemplary BAW resonator 110 (i.e., each of the BAW resonators 1015-1 to 1015-5 and 1020-1 to 1020-4 is a separate instance of the BAW resonator 110). In this example, the series BAW resonators 1015-1 to 1015-5 are coupled in series between the input and the output of the bandpass filter 1010 and each shunt BAW resonator 1020-1 to 1020-4 is coupled between adjacent series BAW resonators. It is to be appreciated that a bandpass filter may include a different number of BAW resonators than shown in the example in FIG. 10. In other examples, a filter may include BAW resonators coupled in a lattice configuration or a combination of a ladder configuration and a lattice configuration.

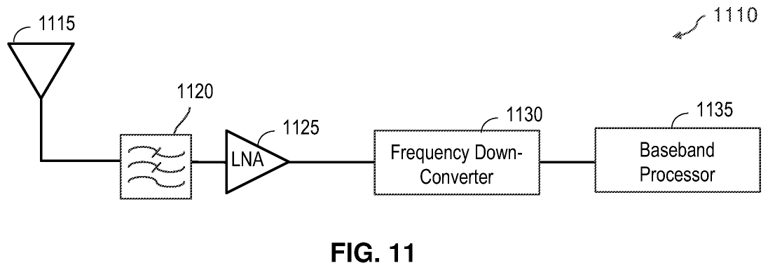

A bandpass filter incorporating BAW resonators may be used in the receive path or the transmit path of a wireless device. In this regard, FIG. 11 shows an example of a receive path 1110 of a wireless device according to certain aspects. The receive path 1110 includes an antenna 1115, a bandpass filter 1120, a low noise amplifier (LNA) 1125, a frequency-down converter 1130, and a baseband processor 1135. In this example, the bandpass filter 1120 is coupled between the antenna 1115 and the input of the LNA 1125. The bandpass filter 1120 may include BAW resonators (e.g., multiple instances of the BAW resonator 110). The frequency-down converter 1130 is coupled between the output of the LNA 1125 and the baseband processor 1135.

In operation, the bandpass filter 1120 receives radio frequency (RF) signals from the antenna 1115 and filters the received RF signals to pass an RF signal within a desired frequency band. The LNA 1125 amplifies the RF signal from the bandpass filter 1120 and the frequency-down converter 1130 down converts the amplified RF signal into a baseband signal. The baseband processor 1135 is configured to process the baseband signal to recover data from the filtered baseband signal. The processing may include sampling, demodulation, decoding, etc.

It is to be appreciated that the present disclosure is not limited to the exemplary terminology used above to describe aspects of the present disclosure. For example, a lateral feature along the perimeter of a resonator may also be referred to as a border ring, a border frame, or another term.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “approximately”, as used herein with respect to a stated value or a property, is intended to indicate being within 10% of the stated value or property and/or within typical manufacturing and design tolerances.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel feature disclosed herein.

What is claimed is:

1. A method for reducing coupling coefficient variation, comprising:
receiving one or more measured coupling coefficients of one or more acoustic resonators;
determining a coupling coefficient change based on the one or more measured coupling coefficients; and
determining a change in a dimension of a lateral feature based on the determined coupling coefficient change.

2. The method of claim 1, wherein the dimension of the lateral feature comprises a height of the lateral feature.

3. The method of claim 1, wherein the dimension of the lateral feature comprises a width of the lateral feature.

4. The method of claim 1, wherein the one or more acoustic resonators comprise one or more bulk acoustic wave resonators.

5. The method of claim 1, further comprising changing the dimension of the lateral feature on each one of the one or more acoustic resonators based on the determined change in the dimension of the lateral feature.

6. The method of claim 5, wherein:
the dimension of the lateral feature comprises a height of the lateral feature; and
changing the dimension of the lateral feature on each one of the one or more acoustic resonators comprises trimming the height of the lateral feature on each one of the one or more acoustic resonators based on the determined change in the dimension of the lateral feature.

7. The method of claim 6, wherein trimming the height of the lateral feature on each one of the one or more acoustic resonators comprises trimming the height of the lateral feature on each one of the one or more acoustic resonators using ion beam etching.

8. The method of claim 5, wherein, for each one of the one or more acoustic resonators, the lateral feature is located along a perimeter of an active region of each one of the one or more acoustic resonators.

9. The method of claim 5, wherein, for each one of the one or more acoustic resonators, the lateral feature comprises a portion of an electrode of each one of the one or more acoustic resonators.

10. The method of claim 1, wherein determining the coupling coefficient change comprises:
determining a mean of the one or more measured coupling coefficients; and
determining a difference between the mean of the one or more measured coupling coefficients and a target coupling coefficient.

11. The method of claim 1, wherein the one or more acoustic resonators comprise one acoustic resonator, and determining the coupling coefficient change comprises determining a difference between the measured coupling coefficient of the one acoustic resonator and a target coupling coefficient.

12. The method of claim 1, wherein determining the coupling coefficient change comprises:
interpolating a coupling coefficient based on the one or more measured coupling coefficients; and
determining a difference between the interpolated coupling coefficient and a target coupling coefficient.

13. The method of claim 12, wherein interpolating the coupling coefficient includes performing one of linear interpolation, piecewise interpolation, or radial symmetric interpolation.

14. An apparatus for reducing coupling coefficient variation, comprising:
means for receiving one or more measured coupling coefficients of one or more acoustic resonators;
means for determining a coupling coefficient change based on the one or more measured coupling coefficients; and
means for determining a change in a dimension of a lateral feature based on the determined coupling coefficient change.

15. The apparatus of claim 14, wherein the dimension of the lateral feature comprises a height of the lateral feature.

16. The apparatus of claim 14, wherein the dimension of the lateral feature comprises a width of the lateral feature.

17. The apparatus of claim 14, wherein the one or more acoustic resonators comprise one or more bulk acoustic wave resonators.

18. The apparatus of claim 14, wherein the means for determining the coupling coefficient change comprises:
means for determining a mean of the one or more measured coupling coefficients; and
means for determining a difference between the mean of the one or more measured coupling coefficients and a target coupling coefficient.

19. The apparatus of claim 14, wherein the one or more acoustic resonators comprise one acoustic resonator, and the means for determining the coupling coefficient change comprises means for determining a difference between the measured coupling coefficient of the one acoustic resonator and a target coupling coefficient.

20. The apparatus of claim 14, wherein the means for determining the coupling coefficient change comprises:
means for interpolating a coupling coefficient based on the one or more measured coupling coefficients; and
means for determining a difference between the interpolated coupling coefficient and a target coupling coefficient.

21. The apparatus of claim 20, wherein the means for interpolating includes means for performing one of linear interpolation, piecewise interpolation, or radial symmetric interpolation.

22. An apparatus, comprising:
a processor;
a memory coupled with the processor; and
instructions stored in the memory and executable by the processor to cause the apparatus to:
receive one or more measured coupling coefficients of one or more acoustic resonators;
determine a coupling coefficient change based on the one or more measured coupling coefficients; and
determine a change in a dimension of a lateral feature based on the determined coupling coefficient change.
